(19) United States
(12) Patent Application Publication
(10) Pub. No.: US 2026/0171365 A1
(43) Pub. Date: Jun. 18, 2026

(54) A MICROWAVE PLASMA REACTOR WITH A PLURALITY OF EMITTERS AND ABSORBERS AND A METHOD FOR PLASMA PROCESSING A WORKPIECE USING SUCH A MICROWAVE PLASMA REACTOR

(71) Applicant: EVATEC AG, Trübbach (CH)

(72) Inventors: Fabio ISA, Zürich (CH); Luca MARCACCIOLI, Perugia (IT); Marco CAPODURl, Cortona (IT); Hamza EL GHANNUDI, Perugia (IT); Günter RATZ, Freiburg (DE); Jürgen WEICHART, Balzers (LI); Kevin HUG, Walenstadt (CH); Jörg PATSCHEIDER, Meilen (CH)

(21) Appl. No.: 19/119,327

(22) PCT Filed: Oct. 13, 2023
(86) PCT No.: PCT/EP2023/078483

§ 371 Date: Apr. 8, 2025

(30) Foreign Application Priority Data
Oct. 28, 2022 (CH) 001276/2022

(51) Int. Cl. H01J 37/32

(52) U.S. Cl. CPC H01J 37/32311; H01J 37/3222; H01J 37/32229; H01J 37/32266; H01J 37/3244; H01J 37/32522; H01J 37/32724

(57) ABSTRACT

A microwave plasma reactor comprises a plasma chamber, a workpiece holder, a gas flow system, one or more microwave generators, a plurality of microwave emitters each comprising an amplifier, a phase shifter and an emitting element mounted at the plasma chamber, wherein each of the microwave emitters is connected to at least one of the one or more microwave generators. The microwave plasma reactor further comprises one or more microwave absorbers, wherein each of the microwave absorbers comprises an absorbing element mounted at the plasma chamber. An emitter control unit controls an amplification of the amplifier and a phase shift of the phase shifter for each of the microwave emitters to generate a desired distribution of microwave power from the emitter array to one or multiple desired locations within the plasma chamber. Further, a method for plasma processing a workpiece is provided.

### TECHNICAL FIELD

The present invention pertains to a microwave plasma reactor as well as to a method for plasma processing a workpiece such as a substrate/wafer using such a microwave plasma reactor.

### BACKGROUND OF THE INVENTION

Plasma-based processing such as plasma enhanced (assisted or activated) chemical vapor deposition (PECVD) or plasma enhanced reactive ion etching (PERIE) is employed extensively in a wide variety of applications in the semiconductor industry, e.g., for processing workpieces such as silicon or glass substrates/wafers. Thereby, radio frequency (RF<300 MHz, typically <30 MHz, RF standard operation frequency of 13.56 MHz) generated plasmas are most often employed, however, plasmas generated with a microwave source (MW≥300 MHz, typically >900 MHz, MW standard operation frequency of 2.45 MHz), typically a magnetron, allow to achieve denser plasmas. A drawback of present microwave sources for plasma generation is that they commonly generate plasmas that are not uniform and/or the density of which cannot be spatially varied/adjusted, since the geometry of the plasma is constrained by the geometry of the plasma reactor as well as by the waveguide(s) used for transferring the microwave radiation from the magnetron to the processing chamber. Due to the inability to tune the plasma, it is difficult to account for edge effects when large (e.g., diameter ≥300 mm) substrates are to be processed.

High plasma densities requiring high source power are for instance needed for the deposition of diamond-like carbon (DLC) films as well as for manufacturing synthetic diamond material using CVD techniques. In the field of CVD diamond synthesis, it has been found that microwave plasma is the most effective method for driving CVD diamond deposition in terms of the combination of power efficiency, growth rate, growth area, and purity of product which is obtainable. To form a uniform, stable, large area plasma across the surface of a large area substrate for achieving uniform CVD diamond growth over large areas, there is a need to improve upon existing arrangements in order to provide larger CVD growth areas, better uniformity, higher growth rates, better reproducibility, better power efficiency and/or lower production costs.

Hence, there is a need for improved microwave plasma reactors which overcome the stated drawbacks and meet the mentioned requirements, and which are especially suited for microwave plasma CVD diamond synthesis.

### SUMMARY OF THE INVENTION

It is an object of the present invention to provide an improved microwave plasma reactor capable of generating stable, uniform plasmas the density of which can be spatially varied/adjusted in a cost- and energy-efficient manner, in particular which allows to tune the plasma in order to account for edge effects when large (e.g., diameter ≥300 mm) substrates are to be processed, and which is in particular suitable for microwave plasma CVD diamond synthesis to achieve larger CVD growth areas, better uniformity, higher growth rates, better reproducibility, better power efficiency and/or lower production costs. This object is achieved by the microwave plasma reactor specified in claim 1.

It is a further goal of the present invention to provide an improved method for cost- and energy-efficient processing of workpieces such as substrates/wafers, in particular which allows highly uniform processing large (e.g., diameter ≥300 mm) substrates/wafers, and which is in particular suitable for microwave plasma CVD diamond synthesis to achieve larger CVD growth areas, better uniformity, higher growth rates, better reproducibility, better power efficiency and/or lower production costs. This aim is achieved by the method laid out in claim 20.

Specific embodiments of the apparatus and method according to the present invention are given in the dependent claims.

A microwave plasma reactor according to the present invention comprises:
a plasma chamber with a base, a top, and a side wall extending from the base to the top, the plasma chamber in particular being prism-shaped or cylindrical, and the top in particularly forming a curved dome;
a workpiece holder disposed at the base and comprising a supporting surface for supporting a workpiece, such as a substrate;
a gas flow system for feeding process gas into the plasma chamber and/or removing gas from the plasma chamber;
one or more microwave generators adapted to generate microwaves at a frequency f;
a plurality of microwave emitters each comprising an amplifier, in particular a solid-state amplifier, a phase shifter and an emitting (or feeding) element, in particular an antenna, wherein each of the microwave emitters is connected to at least one of the one or more microwave generators, and wherein the emitting elements of the plurality of microwave emitters are mounted at the plasma chamber, in particular at the side wall, and form an emitter array;
one or more microwave absorbers adapted to absorb microwaves at the frequency f, wherein each of the microwave absorbers comprises an absorbing element, in particular an antenna terminated by a matching load, e.g., a 50 Ohm load, wherein the absorbing elements of the one or more microwave absorbers are mounted at the plasma chamber, in particular at the side wall, and form an absorber array;
an emitter control (or beam steering) unit for individually controlling an amplification of the amplifier and a phase shift of the phase shifter for each or most of the microwave emitters and adapted to generate a desired distribution of microwave power from the emitter array to one or multiple desired locations within the plasma chamber.

With such a microwave plasma reactor it is possible to produce a variable electric field (E-field) within the plasma chamber so that a plasma with a desired density can be generated at a specific region within the plasma chamber. By being able to control the plasma by varying the E-field the plasma can be tuned as required, e.g., to achieve the desired uniformity when depositing or etching a layer of material.

The external walls of the plasma chamber are made of metal, e.g., aluminium, while the inner walls can be made of metal or an absorbing microwave material.

The workpiece holder (or pedestal) is made of metal, e.g., molybdenum (especially for producing synthetic diamond). The edges of workpiece holder may be filleted in order to reduce E-field spikes at the workpiece holder.

Instead of using a plurality of absorbing elements, possibly only a single absorbing element is employed, e.g., in the form of a continuous piece of absorbing material essentially interposed or interspersed between the emitting elements/antennas. Such a single absorbing element is still considered to form an absorber array, due to its (complementary) arrangement with respect to the plurality of emitting elements forming an emitter array.

The intensity and uniformity of the plasma can for instance be achieved by establishing a time-independent distribution of the E-field at the plasma region or by changing the E-field distribution over the plasma region with a time period shorter than the plasma extinguishing time, e.g., by periodically “scanning” a focal point/spot of the E-field across the plasma region. In the latter case, the scanning speed or dwell time at a certain location of the focal point/spot or a point density (or distance between consecutive locations where the focal point/spot temporarily dwells in a specific area) may be varied.

In an embodiment of the reactor the one or more microwave absorbers are arranged and configured to absorb a portion of the microwave power radiated by the emitting elements, in particular scattered and reflected microwave power, such that radiation from the emitting elements appears not to be affected by the plasma chamber, in particular that essentially free-field radiation takes place from the emitting elements, more particularly approximating a hypothetical situation with infinite open radiation boundary condition.

In a further embodiment of the reactor the emitter array and the absorber array are both conformal arrays with a common central axis coinciding with a central axis of the plasma chamber, wherein the emitter array is in particular interleaved with or nested within the absorber array at least partially.

The emitting/feeding elements are thus mounted parallel to the workpiece holder in such a way that the radiated tangent E-field propagates over the supporting surface onto which the workpiece is placed for processing. By appropriately setting the phase (and amplitude) of each emitting element it is possible to focus/direct the E-field over the workpiece and to move the focal point/spot as desired/required.

In a further embodiment of the reactor the emitting/feeding elements forming the emitter array and the absorbing elements forming the absorber array are located at the side wall of the plasma chamber and are arranged in one or more layers stacked upon each other between the base and the top, wherein in particular emitting elements and absorbing elements are alternatingly disposed in some layers, and wherein in particular all other layers exclusively consist of absorbing elements, wherein in particular the other layers are a first number of top layers and/or a second number of bottom layers.

In a further embodiment of the reactor the positions of the emitting elements and/or of the absorbing elements are continually rotated from one layer to the next consecutive layer, from a lower layer to an upper layer, wherein in particular the emitting elements and the absorbing elements are arranged in a helical- or spiral-shaped pattern.

In a further embodiment of the reactor the emitting elements and the absorbing elements have essentially the same geometry.

In a further embodiment of the reactor the lower-most of the layers comprising emitting elements is in the same plane as the workpiece holder, in particular as the supporting surface for supporting the workpiece.

In a further embodiment of the reactor the emitting elements and the absorbing elements are short-truncated waveguides, horn or double-ridged horn antennas, in particular with a coaxial-feed, adapted to operate at the frequency f.

The emitting/feeding elements/antennas and the absorbing elements/antennas in particular do not extend into an interior space of the plasma chamber. The emitting/feeding elements/antennas and the absorbing elements/antennas are in particular flush with an interior surface of the side wall of the plasma chamber.

In a further embodiment of the reactor the frequency f is in a range from 500 MHz to 15 GHz, in particular in the range from 900 MHz to 5.8 GHz, more particularly in the range from 2 GHz to 2.5 GHZ. The frequency f is for instance in the 915 MHz, 2.45 GHz or 5.8 GHz industrial, scientific and medical (ISM) band.

In a further embodiment of the reactor the emitter control unit is adapted to move a focal point/spot of the microwave power (E-field) emitted by the emitter array along a desired two- or three-dimensional path over the workpiece holder in order to produce a plasma with a desired shape (and density) within a desired confined space over the workpiece holder. The scanning pattern of the microwave power (E-field) may for instance be spiral shaped (within a plane or within a 3D body). The scanning pattern may in particular be a 3D scanning pattern, e.g., for processing non-planar workpieces/substrates.

In a further embodiment of the reactor in order to maintain the plasma within the desired confined space the emitter control unit is adapted to move the focal point of the microwave power repeatedly essentially along the two- or three-dimensional path determining the desired confined space, wherein a time period for each repetition is in particular shorter than a plasma extinguishing time.

In a further embodiment of the reactor the emitter control unit is adapted to adjust a length of time (i.e., a dwell time) and/or level of power at which microwaves emitted by the emitter array are focused on a certain point or area over the workpiece holder or to adjust a point density (or the distance between consecutive locations where the focal point/spot temporarily dwells in a specific area) in order to compensate non-uniformity effects in deposition or etching (and thus achieve uniform deposition or etching of the workpiece). In this way the scanning speed or the dwell time at a certain location of the focal point/spot or the point density may be varied, i.e., either increased or decreased, as required, e.g., to obtain a desired level of deposition or etching of the workpiece (in particular at different locations/areas of the workpiece).

In a further embodiment of the reactor the matched load comprises cooling means, e.g., a heat sink, in particular with a cooling fluid, such as air or a liquid, e.g., water.

In a further embodiment of the reactor the plasma chamber is vacuum-sealed.

In a further embodiment of the reactor in order to provide a proper sealing of the plasma chamber a dielectric window, such as a pressurized quartz window, is arranged in front of or inside the emitting elements and the absorbing elements or the coaxial-feed comprises a hermetic feedthrough coaxial connector.

In a further embodiment of the reactor in order to reduce an E-field around a coaxial pin of the coaxial-feed, so as to avoid unwanted spike plasma around the coaxial pin, a (thin) dielectric layer, such as an alumina layer, is arranged in front of the waveguide of the emitting elements and the absorbing elements, or a (thin) dielectric cylinder or tube, such as an alumina or ceramic cylinder or tube, is arranged around the coaxial pin.

In a further embodiment of the reactor a container made of a dielectric, microwave permeable material (that does not substantially absorb the emitted microwaves at a frequency f), such as an alumina, fused silica, quartz or glass container, is located within the plasma chamber, wherein either the workpiece holder is located within the container or the container is mounted on the workpiece holder, and wherein the container is vacuum-sealed against the plasma chamber, which may be filled with air, and wherein a/the plasma is intended to be formed within the container. The top of the container may be a curved dome or have an ellipsoidal shape.

In a further embodiment the reactor further comprises temperature control means, such as cooling and/or heating means, adapted to regulate a temperature of the workpiece holder. The temperature control means are for instance controlled by a temperature control unit.

In a further embodiment the reactor further comprises cooling means adapted to cool the plasma chamber. The plasma chamber may be cooled in order to remove the heat caused by the microwave power, which has not been dissipated in the plasma or the absorbing elements.

In a further embodiment the reactor comprises means for electrically biasing the workpiece/substrate and/or the workpiece/substrate holder.

The number of emitting/feeding and absorbing elements/antennas may be varied depending on the required dimensions and geometry of the plasma chamber.

The phase shifters may be implemented using analogue and/or digital circuitry.

The total emitted power is for instance in the range from 100 W to 10 kW.

The total number of emitting/feeding elements/antennas is for instance in the range from 10 to 40, in particular is 24, and total number of absorbing elements/antennas is for instance in the range from 20 to 100, in particular is 48.

The E-field intensity is in the range from 0.1 kV/m to 22 kV/m.

In the case of no (dielectric) chamber being used, the workpiece holder extends to the side wall on the plasma chamber with a gap between the workpiece holder and the side wall in a range from 0.5 mm to 10 mm (dependent on the frequency f).

The complete microwave plasma reactor for instance has a diameter in a range from 400 to 800 mm, in particular of mm.

According to a further aspect of the present invention a method for processing a workpiece, such as a substrate/wafer, is proposed, comprising the steps of:
providing a microwave plasma reactor according to any one of the embodiments mentioned above;
arranging the workpiece on the workpiece holder;
feeding process gas into the plasma chamber and/or evacuating gas from the plasma chamber;
feeding microwave power from the one or more microwave generators to the plurality of microwave emitters;
individually controlling the amplification of the amplifier and the phase shift of the phase shifter for each or most of the microwave emitters such that a desired distribution of microwave power is generated by the emitting elements forming the emitter array at one or multiple desired locations within the plasma chamber, in particular to ignite and/or maintain a plasma with a desired plasma density within a desired confined space within the plasma chamber;
absorbing by the plurality of microwave absorbers a portion of the microwave power emitted by the plurality of microwave emitters;
forming a layer of material, in particular diamond or diamond-like carbon (DLC), on a surface of the workpiece or etching the surface of the workpiece.

The pressure of the (process) gas within plasma chamber or the (dielectric) container is in the range from 10 to 120 Torr, in particular for diamond deposition. For the plasma ignition the pressure may be as low as 4 Torr. For plasma etching applications the pressure may also be below 10 Torr.

In an embodiment the method is part of a chemical vapor deposition (e.g., plasma assisted/activated/enhanced, PECVD) process, in particular for depositing a diamond or diamond-like carbon (DLC) layer on the workpiece (using methane as process gas), or of an etching process (e.g., plasma enhanced reactive ion etching, PERIE), in particular a soft etching process, in particular wherein the energy of ions in the plasma is less than 10 eV.

In a further embodiment of the method controlling the amplification and the phase shift for the microwave emitters is adapted such that the plasma is confined to a hemisphere above the workpiece, and in particular in contact with the workpiece, especially in the case of processing using chemical vapor deposition (CVD).

In a further embodiment of the method controlling the amplification and the phase shift for the microwave emitters is adapted such that the plasma is not in contact with the workpiece, and is in particular confined to a spot or sphere above the workpiece, for instance in the case of temperature sensitive processing, especially when the plasma is employed to generate radicals.

In a further embodiment of the method controlling the amplification and the phase shift for the microwave emitters is adapted such that the plasma is confined to a small space within the plasma chamber, such as a spot or a sphere, and the plasma is moved within the plasma chamber along a desired two- or three-dimensional path, wherein during moving of the plasma along the path in particular a speed at which the plasma is moved is varied and/or an intensity of the plasma is varied (in particular to achieve uniform deposition or etching of the workpiece).

It is specifically pointed out that combinations of the embodiments mentioned above can result in even further, more specific embodiments.

### BRIEF DESCRIPTION OF THE DRAWINGS

The present invention is further explained below by means of non-limiting specific embodiments and with reference to the accompanying drawings, which show the following:

FIG. 1 a schematic cross-sectional side view of an exemplary embodiment of a microwave plasma reactor according to the present invention;

FIG. 2 a schematic cross-sectional side view of a further exemplary embodiment of a microwave plasma reactor according to the present invention (with a quartz container located within the plasma chamber);

FIG. 3 a perspective view slightly from above of an embodiment of a microwave plasma reactor according to the present invention, in particular highlighting the emitter and absorber array;

FIG. 4 a perspective view slightly from below of a further embodiment of a microwave plasma reactor according to the present invention, in particular highlighting the emitter and absorber array;

FIG. 5 a) a first layer with both emitting and absorbing elements in a cross-sectional top view of an exemplary embodiment of a microwave plasma reactor according to the present invention, and

FIG. 5 b) a second, consecutive layer with both emitting and absorbing elements in a cross-sectional top view of an exemplary embodiment of a microwave plasma reactor according to the present invention;

FIG. 6 a) a side view of the embodiment of a microwave plasma reactor according to FIG. 4, in particular showing the connectors and coaxial pins of the emitting and absorbing elements, and

FIG. 6 b) an enlarged, detailed side view of the side wall of the microwave plasma reactor of FIG. 6 a), in particular showing the connector and coaxial pin of the emitting/absorbing element;

FIG. 7 an exemplary block diagram of microwave power generation for the emitter array according to the present invention; and

FIG. 8 an exemplary spiral shaped path/scanning pattern of a focal point/spot of the microwave power (E-field) emitted by the emitter array of a microwave plasma reactor according to the present invention.

In the figures, like reference signs refer to like parts.

### DETAILED DESCRIPTION OF THE INVENTION

The core of the present invention is a microwave plasma reactor which is capable of generating a variable E-field within a confined space as well as over time and can thus form a desired distribution of microwave power within the plasma chamber such that the density of a plasma can be spatially varied/adjusted as needed.

Such a microwave plasma reactor is detailed in the following.

FIG. 1 shows a schematic cross-sectional side view of an exemplary embodiment of a microwave plasma reactor 1 according to the present invention. The microwave plasma reactor 1 comprises a plasma chamber 2 with a base 3, a top 4, and a side wall 5 extending from the base 3 to the top 4. A workpiece holder 6 in the form of a pedestal comprising a supporting surface for supporting a workpiece 7, such as a substrate/wafer, is disposed at the base 3. The microwave plasma reactor 1 further features a gas flow system for feeding process gas into the plasma chamber 2 via the gas inlet 8 and/or removing/evacuating gas (e.g., process gas or air) from the plasma chamber 2 via the gas outlet 9. The microwave plasma reactor 1 comprises a plurality of microwave emitters 10 (marked dark/hatched in FIGS. 1 & 2) each comprising an amplifier, in particular a solid-state amplifier, a phase shifter and an emitting (or feeding) element/antenna. Each of the microwave emitters 10 is connected to a microwave generator adapted to generate microwaves at a frequency f. Alternatively, more than one (lower power) microwave generators may be used (instead of a single higher power microwave generator), whereby each of the microwave emitters 10 is connected to at least one of these microwave generators. The emitting elements of the plurality of microwave emitters 10 are mounted at the side wall 5 of the plasma chamber 2 in the form of an emitter array. An emitter control unit is used to individually control an amplification of the amplifier and a phase shift of the phase shifter for each of the microwave emitters 10 (-> beam steering). The emitter control unit is adapted to generate a desired distribution of microwave power from the emitter array to one or multiple desired locations within the plasma chamber 2. The emitters 10 and absorbers 11 (in particular the emitting and absorbing elements) are (essentially) flush with the inner surface of the side wall 5 of the plasma chamber 2. As a characteristic feature of the present invention microwave absorbers 11 adapted to absorb microwaves at the frequency f are mounted at the side wall 5 of the plasma chamber 2 in the form of an absorber array. Each of the microwave absorbers 11 comprises an absorbing element, in particular an antenna terminated by a matching load, e.g., a 50 Ohm load.

The microwave absorbers 11 are arranged and configured to absorb a portion of the microwave power radiated by the emitting elements, in particular scattered and reflected microwave power. The purpose of the microwave absorbers 11 is to achieve that the radiation from the emitting elements is not affected by the plasma chamber 2, such that essentially “free-field” radiation takes place from the emitting elements. In this way, the hypothetical situation with an infinite open radiation boundary condition is essentially approximated.

The amplifiers and phase shifters of the microwave emitters 10 may be located close to the one or more microwave generators, especially before the coaxial-line leading to the emitting (or feeding) element/antenna. Similarly, the absorbing elements of the microwave absorbers 11 may be located distant from the absorbing elements (microwave cavities). It is to be noted that this can be the case even in those instances where the microwave emitters 10 and absorbers 11 are drawn (in a simplified manner) at the side wall 5 of the plasma chamber 2 in the attached figures (although only the emitting and absorbing elements are directly mounted there).

The plasma chamber 2 is prism-shaped or cylindrical with a central axis a, e.g., a cuboid, and the top 4 can for instance be formed as a curved dome (indicated by the dashed line in FIGS. 1 & 2). The external walls of the plasma chamber 2 are made of metal, e.g., aluminium, while the inner walls can be made of metal or an absorbing microwave material.

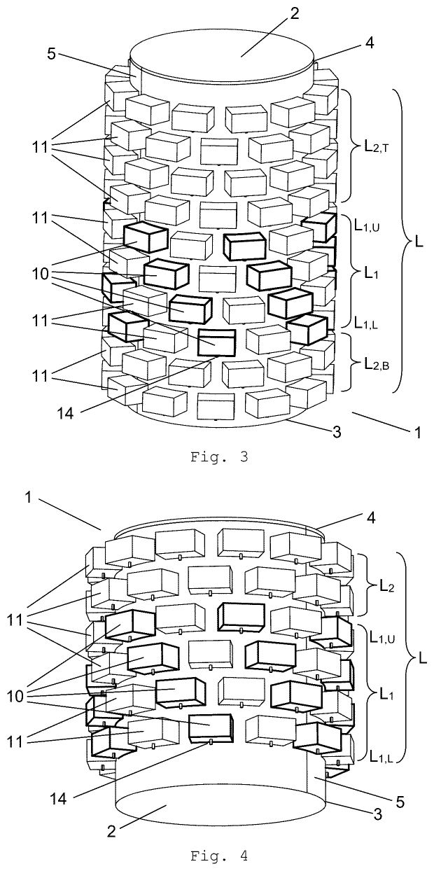

The emitter array and the absorber array are both conformal arrays with a common central axis which coincides with the central axis a of the plasma chamber 2. As can be seen clearly in the subsequent figures FIGS. 3 & 4 the emitter array is nested within the absorber array.

The workpiece holder 6 is made of metal, e.g., molybdenum (especially for manufacturing synthetic diamond). The edges of the workpiece holder 6 may be filleted in order to reduce E-field spikes at the workpiece holder 6. It is to be noted that the workpiece holder 6 comprises a base or bottom part 6_{B}, which extends almost to the side wall 5 of the plasma chamber 2 (with a small gap <10 mm between the side wall 5 and the base part 6_{B}), and a central top part 6_{T}(providing the supporting surface for supporting the workpiece 7), which is distant from the side wall 5 of the plasma chamber 2 (e.g., the top part 6_{T} has a diameter of ¾ or less than the diameter of the plasma chamber 2). The plasma 12 is intended to be present only on or above the top part 6_{T}, i.e., on or above the workpiece 7. For instance, it is desired to generate and sustain a plasma 12 comprising an inner plasma region 12ᵢ and an outer torus-shaped plasma region 12ₒ. In this way, the higher E-field strength in the outer torus plasma region 12ₒ compared with the inner plasma region 12ᵢ allows compensating the loss of plasma species towards the periphery of the plasma 12 and the workpiece 7 in order to achieve uniform deposition and/or etching over the entire workpiece 7 and mitigate edge effects, especially when large (e.g., diameter ≥300 mm) substrates are processed.

The emitting elements arranged lower-most at the side wall 5 of the plasma chamber 2 are located in the same plane as the workpiece holder 6, i.e., at the same level as the supporting surface for supporting the workpiece 7.

The emitting elements and the absorbing elements have essentially the same geometry and are implemented as short-truncated waveguides (alternatively as horn or double-ridged horn antennas) with a coaxial-feed. The operating frequency f is for instance in the 915 MHz, 2.45 GHz or 5.8 GHz industrial, scientific and medical (ISM) band, since standard RF components are readily available for these frequencies.

In a microwave plasma reactor 1 according to FIG. 1 the plasma chamber 2 is vacuum-sealed. In order to achieve this a dielectric window (e.g., a pressurized quartz window) is arranged in front of or inside the emitting elements and the absorbing elements or the coaxial-feed comprises a hermetic feedthrough coaxial connector.

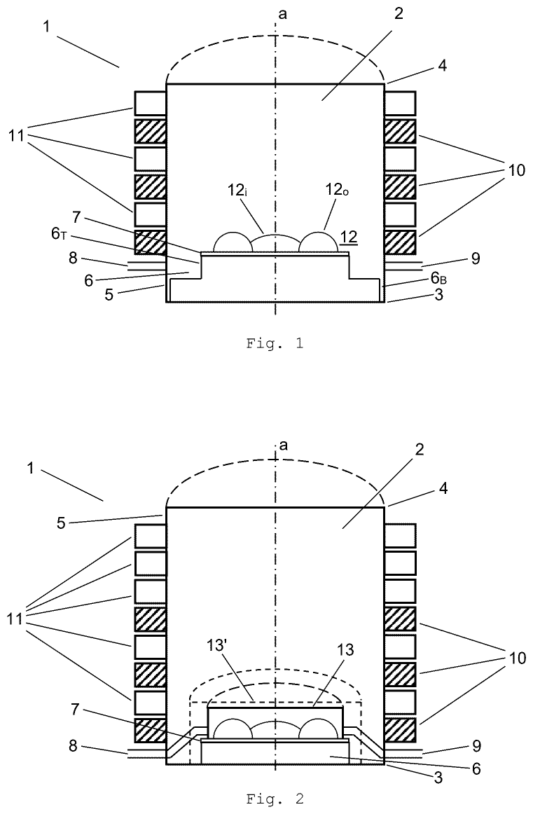

FIG. 2 shows a schematic cross-sectional side view of another exemplary embodiment of a microwave plasma reactor 1 according to the present invention with the following difference compared to the embodiment illustrated in FIG. 1. A container 13 (or 13′) made of a dielectric, microwave permeable material, such as an alumina, fused silica, quartz or glass container, is located within the plasma chamber 2. The container 13 is mounted on the workpiece holder 6. Alternatively, the workpiece holder 6 could be located within the container 13′ (as illustrated in FIG. 2 in short dashed lines). The workpiece holder 6 is restricted to the central region of the plasma chamber 2 (with a diameter of ⅔ or less than the diameter of the plasma chamber 2) and does not extend to the side wall 5 (as opposed to the workpiece holder 6 according to FIG. 1). The container 13 is vacuum-sealed against the plasma chamber 2, which may be filled with air. The plasma is intended to be formed within the container 13, 13′ (nonetheless, we still refer to the entire enclosure 2 as the “plasma chamber”). The top of the container may be a curved dome or have an ellipsoidal shape (as indicated by the long dashed line for the container 13 and the short dashed line for the alternative container 13′). Process gas is fed into the container 13, 13′ via the gas inlet 8 and/or gas (e.g., process gas or air) is removed/evacuated from the container 13, 13′ via the gas outlet 9.

Since the process chamber 2 does not require to be vacuum-sealed no measures need to be taken in order to vacuum seal the emitting elements 10 and the absorbing elements 11 in the embodiment of the microwave plasma reactor 1 according to FIG. 2.

FIG. 3 shows a perspective view slightly from above of an embodiment of a microwave plasma reactor 1 according to the present invention, in particular highlighting the emitter and absorber array. In this embodiment the microwave plasma reactor 1 comprises 24 emitting/feeding elements (=emitter array) and 84 absorbing elements (=absorber array). As can be seen the emitting elements forming the emitter array and the absorbing elements forming the absorber array are located at the side wall 5 of the plasma chamber 2 and are arranged in multiple layers L stacked upon each other between the base 3 and the top 4 parallel to the workpiece holder 6. Hereby, emitting elements 10 and absorbing elements 11 are alternatingly disposed in the four layers L₁ and all other layers L₂ exclusively consist of absorbing elements 11, whereby the other layers L₂ are four top layers L_{2,T} and two bottom layers L_{2,B}. The positions of the emitting elements 10 and of the absorbing elements 11 within the four layers L₁ are continually rotated from one layer to the next consecutive layer, from the lower layer L_{1,L} to the upper layer L_{1,U}. Hereby, the emitting elements 10 and the absorbing elements 11 are arranged in a helical- or spiral-shaped pattern. The lowest-most emitting elements are located in the same plane as the workpiece holder 6, i.e., at the same level as the supporting surface for supporting the workpiece 7 and the two bottom layers L_{2,B} consisting of only absorbing elements are located below the supporting surface for supporting the workpiece 7. The top and bottom layers L_{2,T}, L_{2, B} of absorbing elements ensure that the E-field can be precisely adjusted as desired by achieving that radiation from the emitting elements is not (or only marginally) affected by the plasma chamber 2. The size and shape of the workpiece holder 6 corresponds to the workpiece holder 6 depicted in FIG. 2, i.e., is restricted to the central region of the plasma chamber 2.

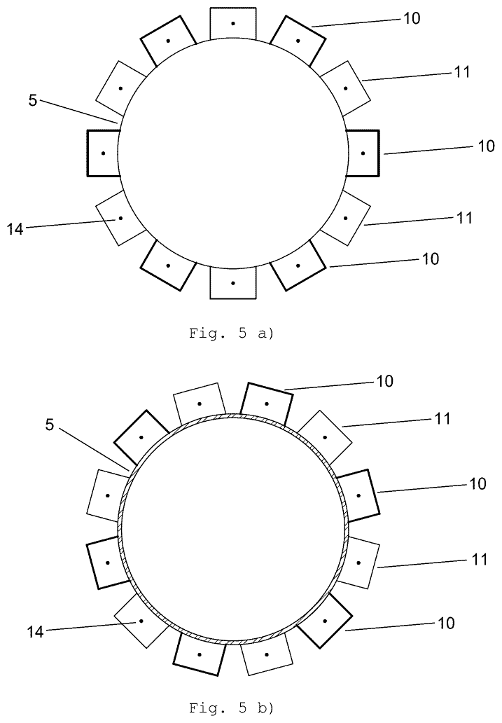

FIG. 4 shows a perspective view slightly from below of another more compact, i.e., less high (compared with FIG. 3), embodiment of a microwave plasma reactor 1 according to the present invention, in particular highlighting the emitter and absorber array with fewer absorbing elements (compared with FIG. 3), namely only 48 instead of 84, i.e., 36 less. As can be seen, in this embodiment the two top most and two bottom most layers comprising only absorbing elements have been removed. On the other hand, the size and shape of the workpiece holder 6 has been changed according to the workpiece holder 6 depicted in FIG. 1, i.e., having the base part 6_{B}, which extends almost to the side wall 5 of the plasma chamber 2, and central top part 6_{T}, which is distant from the side wall 5 of the plasma chamber 2. By taking away the two bottom most and the two top most levels/layers of absorbing elements and reducing the height of the plasma chamber 2, the intensity of the E-field at the inner wall surface of the plasma chamber 6 remains almost the same, meaning that the performance degradation in terms of E-field absorption is essentially negligible.

FIGS. 3 & 4 in particular also show the connectors 14 to the coaxial pins 15 of the emitting and absorbing elements 10 & 11, located on the bottom side of the respective emitting and absorbing elements 10 & 11 in these examples.

FIG. 5 a) shows a first layer comprising alternatingly both microwave emitters 10 and microwave absorbers 11 in a cross-sectional top view (i.e., seen in direction of the central axis a of the plasma chamber 2) of an exemplary embodiment of a microwave plasma reactor 1. FIG. 5 b) shows a second, consecutive layer again comprising alternatingly both microwave emitters 10 and microwave absorbers 11 likewise in a cross-sectional top view. As can be seen, the positions of the microwave emitters 10 and of the microwave absorbers 11 in the second, consecutive layer are rotated (in this example by 15°) relative to the positions of the microwave emitters 10 and microwave absorbers 11 in the first, vertically adjacent layer.

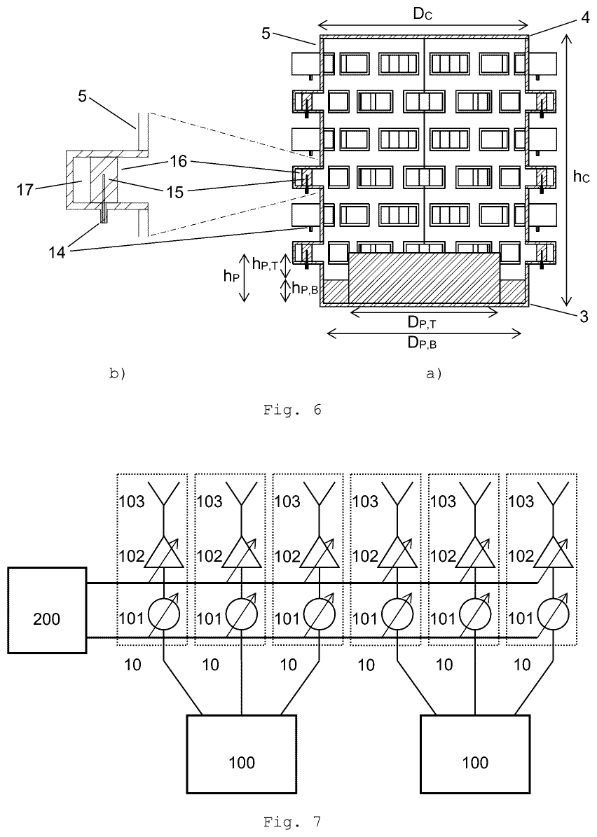

FIG. 6 a) shows a side view of the embodiment of the microwave plasma reactor 1 according to FIG. 4 with four layers L₁ each comprising six emitting and six absorbing elements 10 & 11 and on top of them two layers L₂ each comprising 12 absorbing elements 11, each of the total of six layers L being rotationally offset with respect to the subjacent layer. As an example, the circular cylindrically shaped microwave plasma reactor 1 of FIG. 4/6 a) has the following dimensions. The plasma chamber 2 has a diameter D_{C}=410 mm and a height h_{C}=535 mm from the base 3 to the top 4 of the plasma chamber 2. The base/bottom part 6_{B} of the workpiece holder/pedestal 6 has a diameter of D_{P,B}=D_{C}−2 mm=408 mm and a height of h_{P,B}=46 mm, and the central/top part 6_{T} of the workpiece holder/pedestal 6 has a diameter of D_{P,T}=300 mm and a height (above the base part) of h_{P,T}=100 mm, so that the total height of the workpiece holder/pedestal 6 equals h_{P}=146 mm. Typically, the outer torus plasma region 120 of the plasma 12 then has a diameter of 200 mm at an E-field strength of |Eₚₗ|=9.5e3 V/m±10% and the inner plasma region 12ᵢ of the plasma 12 has a diameter of 150 mm at an E-field strength of |Eₚₗ|=11.5e3 V/m±10%, whereby the E-field strength |E_{C}| in the plasma chamber 2 is less than 18e3 V/m.

The microwave cavities of the emitting and absorbing elements (waveguides) as well as the connectors to the coaxial pins of the coaxial-feeds through which the microwave power is delivered from the one or more microwave generators can be seen in FIG. 6 a). In FIG. 6 b) this is shown in more detail in an enlarged side view of the (left) side wall 5 of the microwave plasma reactor 1 of FIG. 6 a). Here it is clearly visible that the microwave cavity 17 (waveguide) of the emitting/absorbing element is flush with the inner surface of the plasma chamber side wall 5. The coaxial pin 15 of the coaxial-feed is arranged inside the microwave cavity 17. In the example illustrated in FIG. 6 b) the connector 14 to the coaxial pin 15 is located on the underside of the microwave cavity 17 and the coaxial pin 15 is vertically oriented within the microwave cavity 17. A dielectric cylinder 16 (or tube) is mounted in the microwave cavity 17 around coaxial pin 15 in order to reduce the E-field around the coaxial pin 15, thus preventing unwanted spike plasma around the coaxial pin 15. In some areas in the vicinity of the emitter and absorber waveguides 17 and especially close to the alumina cylinder 16 inside the waveguides/microwave cavities 17 the E-field strength can be higher than 18e3 V/m. The cylinder 16 may be made of alumina or a ceramic material.

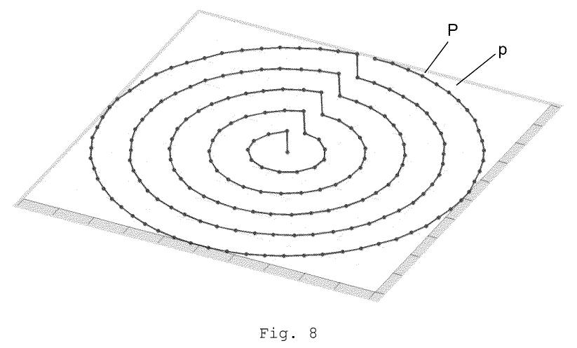

FIG. 7 depicts an exemplary block diagram of microwave power generation for the emitter array according to the present invention. As can be seen, each microwave emitter 10 (e.g., six emitters in FIG. 7) comprises an amplifier 101 with an adjustable amplification, a phase shifter 102 with an adjustable phase shift and an emitting element/antenna 103. Furthermore, each microwave emitter 10 is connected to a microwave generator 100 (e.g., two generators in FIG. 7), which deliver microwave power to the emitters 10. An emitter control unit 200 (for beam control/forming) individually adjusts the amplification of each amplifier 101 and the phase shift of each phase shifter 102 in order to focus and vary the microwave power from the emitter array at a desired location within the plasma chamber 2. By changing the phase shift provided by the emitter control unit 200 to the emitters 10 it is possible to focus the radiated E-field in different points P on the surface of the workpiece 7 as shown in FIG. 8. By changing the amplification provided by the emitter control unit 200 to the emitters 10 it is possible to vary the strength/intensity of the radiated E-field and thereby the density of the plasma generated by the E-field.

FIG. 8 illustrates an exemplary spiral shaped path p/scanning pattern of a focal point/spot P of the microwave power (E-field) emitted by the emitter array of a microwave plasma reactor according to the present invention. The path p comprises a large number of individual/discrete points P. In order to ignite a plasma across the entire surface of the workpiece the emitter control unit 200 successively focuses the microwave power from the emitter array along the path p at the individual points P, one after the other. By repeatedly “scanning” the focal point P of the microwave power (E-field) along this path p the plasma is maintained (similarly to refreshing a raster-based display such as a cathode ray tube where the individual pixels need to be (re-) exited periodically in order to maintain their brightness). Thereby, the time period for each repetition must be shorter than a plasma extinguishing time. The phase shift and amplification settings to achieve a certain desired plasma shape and density can be stored in the memory of the emitter control unit 200 as a set/array of N times M times 2 (i.e., phase & amplitude) values, where N is the number of emitters 10 (e.g., N=24) and M is the number of points comprised in the path p (e.g., M=200). These values may be predetermined (offline) or computed based on plasma or process specifications (online) and potentially even in real-time as part of a closed-loop control system. In addition to the phase and amplitude values for each point P along the path p a time value representing the length of time during which microwave power is radiated by the emitter array to an individual point P (i.e., a dwell time) may also be stored (-> set/array of N×M×3 data values). Alternatively (or additionally) to the dwell time, a point density (i.e., a distance between points in a certain area) may be adjusted in order to control the uniformity of material deposition or etching.

### LIST OF REFERENCE SYMBOLS

1 microwave plasma reactor
2 plasma chamber
3 base of plasma chamber
4 top of plasma chamber
5 side wall of plasma chamber
6 workpiece holder, pedestal
6_{B} base/bottom part of workpiece holder
6_{T} central/top part of workpiece holder
7 workpiece, e.g., substrate/wafer
8 gas inlet of gas flow system
9 gas outlet of gas flow system
10 microwave emitter
11 microwave absorber
12 plasma
12ᵢ inner plasma region
12ₒ outer torus plasma region
13 dielectric container mounted on the workpiece holder
13′ dielectric container enclosing the workpiece holder
14 connector to coaxial pin of coaxial-feed
15 coaxial pin of coaxial-feed of emitting/absorbing element
16 dielectric cylinder or tube around coaxial pin
17 microwave cavity (waveguide) of emitting/absorbing element
100 microwave generator
101 amplifier
102 phase shifter
103 emitting element/antenna
200 emitter control unit/beam steering unit
a central axis of plasma chamber (& common central axis of emitter & absorber array)
D_{C} diameter of the plasma chamber
D_{P,T} diameter of workpiece holder top
D_{P,B} diameter of workpiece holder base
h_{C} height of plasma chamber
h_{P} total height of workpiece holder
h_{P,T} height of workpiece holder top
h_{P,B} height of workpiece holder base
L layers with emitting/absorbing elements
L₁ layers with both emitting and absorbing elements
L₂ layers with only absorbing elements
L_{2,T} top layers with only absorbing elements
L_{2,B} bottom layers with only absorbing elements
L_{1,L} lower(-most) layer with both emitting and absorbing elements
L_{1,U} upper(-most) layer with both emitting and absorbing elements
p 2D/3D path along which the focal point of the microwave power is moved (repeatedly), which determines the desired confined space of the plasma
P focal point of the microwaves/microwave power emitted by the emitter array (-> plasma spot)

1. A microwave plasma reactor comprising:
a plasma chamber with a base, a top, and a side wall extending from the base to the top;
a workpiece holder disposed at the base and comprising a supporting surface for supporting a workpiece;
a gas flow system for feeding process gas into the plasma chamber and/or removing gas from the plasma chamber;
one or more microwave generators adapted to generate microwaves at a frequency f;
a plurality of microwave emitters each comprising an amplifier, a phase shifter and an emitting element, wherein each of the plurality of microwave emitters is connected to at least one of the one or more microwave generators, and wherein the emitting elements of the plurality of microwave emitters are mounted at the plasma chamber, and form an emitter array;
one or more microwave absorbers configured to absorb microwaves at the frequency f, wherein each of the one or more microwave absorbers comprises an absorbing element, wherein the absorbing elements of the one or more microwave absorbers are mounted at the plasma chamber, and form an absorber array; and,
an emitter control unit configured to control an amplification of the amplifier and a phase shift of the phase shifter for each or most of the plurality of microwave emitters and to generate a desired distribution of microwave power from the emitter array to one or multiple desired locations within the plasma chamber.

2. The microwave plasma reactor according to claim 1, wherein the one or more microwave absorbers are arranged and configured to absorb a portion of the microwave power emitted by the emitting elements.

3. (canceled)

4. The microwave plasma reactor according to claim 1, wherein the emitting elements forming the emitter array and the absorbing elements forming the absorber array are located at the side wall of the plasma chamber and are arranged in one or more layers (L) stacked upon each other in a direction from the base to the top.

5. The microwave plasma reactor according to claim 1, wherein the emitting elements and/or the absorbing elements are arranged in a helical- or spiral-shaped pattern.

6. (canceled)

7. The microwave plasma reactor according to claim 4, wherein a layer of the emitting elements is arranged on a same level with respect to a direction from the base to the top as the workpiece holder.

8. The microwave plasma reactor according to claim 1, wherein the emitting elements and the absorbing elements are at least one of short-truncated waveguides, horn antennas and double-ridged horn antennas.

9. The microwave plasma reactor according to claim 1, wherein the frequency f is in a range from 500 MHz to 15 GHz.

10. The microwave plasma reactor according to claim 1, wherein the emitter control unit is configured to move a focal point of the microwave power emitted by the emitter array along a desired two- or three-dimensional path (p) over the workpiece holder.

11. (canceled)

12. The microwave plasma reactor according to claim 1, wherein the emitter control unit is configured to adjust a duration and/or level of power at which microwaves emitted by the emitter array are focused on a certain point (P) or area over the workpiece holder.

13. The microwave plasma reactor according to claim 1, wherein each of the absorbing elements of the one or more microwave absorbers comprises a cooling element.

14.-17. (canceled)

18. The microwave plasma reactor according to claim 1, further comprising a temperature control element configured to regulate a temperature of the workpiece holder.

19. The microwave plasma reactor according to claim 1, further comprising a further cooling element configured to cool the side wall of the plasma chamber (2).

20. A method for processing a workpiece, comprising:
providing a microwave plasma reactor according to claim 1;
arranging the workpiece on the workpiece holder;
feeding process gas into the plasma chamber and/or evacuating gas from the plasma chamber;
feeding microwave power from the one or more microwave generators to the plurality of microwave emitters;
controlling an amplification of the amplifier and a phase shift of the phase shifter for each or most of the microwave emitters and generating a desired distribution of microwave power by the emitting elements at one or multiple desired locations within the plasma chamber;
forming a layer of material on a surface of the workpiece or etching a surface of the workpiece.

21. The method according to claim 20, comprising depositing a diamond or diamond-like carbon layer on the workpiece.

22. The method according to claim 20, comprising etching the surface of the workpiece.

23. The method according to claim 20, comprising confining a plasma to a hemisphere above the workpiece.

24. The method according to claim 20, comprising confining a plasma to a spot or sphere above the workpiece.

25. The method according to claim 20, comprising moving a plasma within the plasma chamber along a desired two- or three-dimensional path (p).

26. The method according to claim 25, comprising varying at least one of a speed of moving the plasma along the two- or three-dimensional path (p) and an intensity of the plasma.
